(19) United States
(12) Patent Application Publication
(10) Pub. No.: US 2020/0243512 A1
(43) Pub. Date: Jul. 30, 2020

(54) NMOS TRANSISTOR WITH BULK DYNAMICALLY COUPLED TO DRAIN

(71) Applicant: STMicroelectronics International N.V., Schiphol (NL)

(72) Inventors: Vishal Kumar SHARMA, Delhi (IN); Varun KUMAR, Nurmahal (IN)

(73) Assignee: STMicroelectronics International N.V., Schiphol (NL)

(21) Appl. No.: 16/736,949

(22) Filed: Jan. 8, 2020

Related U.S. Application Data
(60) Provisional application No. 62/797,536, filed on Jan. 28, 2019.

(51) Int. Cl. H01L 27/02

(52) U.S. Cl. CPC H01L 27/0288

(57) ABSTRACT

A circuit includes a logic circuit and a driver. The driver includes a first NMOS having a gate coupled to the logic circuit and source coupled to a reference voltage, a PAD coupled to a drain of the first NMOS, and a driver protection circuit. The driver protection circuit includes a second NMOS having a drain coupled to the PAD through a capacitor, source coupled to the reference voltage, and gate coupled to a supply voltage, and a resistor coupled between the drain of the second NMOS and the bulk of the first NMOS. The supply voltage transitions low when an electrostatic discharge (ESD) event raises potential at the PAD with respect to either reference voltage or supply voltage such that the second NMOS turns off, resulting in isolation of the bulk of first NMOS from the reference voltage and coupling of the bulk to the PAD using the capacitor.

### RELATED APPLICATION

This application claims priority to U.S. Provisional Application for Patent No. 62/797,536, filed Jan. 28, 2019, the contents of which are incorporated by reference in their entirety.

### TECHNICAL FIELD

This disclosure relates generally to integrated circuit devices, and more particularly, to an integrated circuit device with improved protection against electrostatic discharge (ESD) stress at an input-output PAD of the integrated circuit device.

### BACKGROUND

Electrostatic discharges (ESD) are of concern for developers of integrated circuits (ICs). An ESD voltage may appear at an input-output PAD of the IC when, for example, a voltage is picked up by a conductor that runs between the PAD and a circuit node external to the device. The PAD is a small conductive area on a chip that forms a circuit node where external conductors can be attached to the chip. On the chip, the PAD is connected to the input of an input buffer circuit, or to the output of a driver circuit, or to both. The devices in the driver circuit itself can provide protection against an ESD event, as will be discussed later.

One familiar driver circuit is an inverter formed by two field effect transistors (FETs). An example is shown in FIG. 1, where a PMOS transistor MP1 is connected to conduct between the PAD 13 and a positive input/output (I/O) supply voltage node VDDIO, and an NMOS transistor MN1 is connected to conduct between the PAD 13 and a ground/negative I/O supply voltage node VSSIO. The gates of the transistors MP1 and MN1 are respectively driven by the outputs of logic circuits 11 and 12.

In one binary state of an output signal, the gates of the transistors MP1 and MN1 are driven with voltages that turn off transistor MN1 and turn on transistor MP1 to pull the PAD 13 up to VDDIO. In the other binary output state, the gates of the transistors MP1 and MN1 are driven with voltages that turn off transistor MP1 and turn on transistor MN1 to pull the PAD 13 down to VSSIO.

In a known ESD protection strategy, an ESD network between a supply-ground pair VDDIO, VSSIO and a PAD includes two diodes D1, D2 and an RC triggered NMOS MN2 as shown in FIG. 1. The diode D1 has its cathode coupled to VDDIO and its anode coupled to the PAD 13, the diode D2 has its cathode coupled to the PAD 13 and its anode coupled to VSSIO, and a diode D3 has its cathode coupled to VDDIO and its anode coupled to VSSIO.

The RC triggered NMOS MN2 is not required to be a part of the driver circuit, therefore, depending upon the location of driver circuit and RC triggered NMOS MN2, a parasitic resistance may exist between the supply node VDDIO and ground node VSSIO to which devices in the driver circuit and RC triggered NMOS MN2 are connected as represented by resistors R1 and R2 in FIG. 1.

NMOS transistor MN2 along with diodes D1 and D2 are intended to clamp the voltage during an ESD event between PAD 13 and ground VSSIO or between supply node VDDIO and PAD 13 to a value that will not damage the devices in the circuits on the IC that are connected to the PAD 13. Transistor MN2, when triggered by trigger circuit 14, completes the low resistive current path between PAD 13 and ground VSSIO or between supply VDDIO and PAD 13 to a safe value. This is the intended safe path (known as an ESD network) for current to flow during an ESD event.

Generally, four types of ESD events (in a Human Body Model) are possible at PAD 13. First, the PAD 13 can go positive with respect to VSSIO. Second, the PAD 13 can go positive with respect to VDDIO. Third, the PAD 13 can go negative with respect to VSSIO. Fourth, the PAD 13 can go negative with respect to VDDIO. During the second and third types of ESD events, diodes D1 and D2 can independently discharge the complete ESD charge, and the voltage drop across PMOS MP1 and NMOS MN1 is approximately equal to the forward turn on voltages of those diodes. However, in the first and fourth type of ESD events, NMOS MN2 and resistors R1 or R2 along with diodes D1 or D2 are used to discharge the ESD charge. Hence the total voltage drop across the ESD network can be near to the breakdown voltage of the NMOS MN1 or PMOS MP1.

Thus, during an ESD event of the first or fourth type, the devices MP1, MN1 in the driver circuit can be damaged if the voltage between VDDIO and PAD 13 or PAD 13 and VSSIO becomes equal to or exceeds the breakdown voltage of drain-bulk junction of the PMOS MP1 or NMOS MN1. With the breaking of the semiconductor junction between the drain and bulk of the MP1/MN1, a low resistive current path is established between the two nodes which permits current to flow through the drain into the bulk of MP1 or MN1. In such scenarios, where the total voltage drop across the ESD network is above the breakdown voltage of either device MP1 or device MN1, the ESD network will not be able to protect the devices MP1, MN1 and hence the ESD network is not able to establish a low resistive current path during the event. The large voltage drop in the ESD network could occur for many reasons such as the triggering voltage of RC triggered NMOS MN2 is near to breakdown voltage of devices MP1/MN1 or the parasitic resistance R1 or R2 is significantly high, as well as numerous additional reasons.

In the example of FIG. 1, a positive ESD event is shown during which the PAD 13 goes positive with respect to VSSIO. As soon as the voltage at PAD 13 becomes equal to the sum of the turn on voltage of diode D1 and NMOS MN2 and a voltage drop across R1, a current starts flowing from the PAD 13 into VSSIO through diode D1 and NMOS MN2. However, if this voltage at PAD 13 is larger than the breakdown voltage of MN1, then the semiconductor junction between the drain-bulk of MN1 is broken and the current I1, as shown in FIG. 1, starts flowing through the drain-bulk of MN1.

In the example of FIG. 2, a “negative” ESD event is shown in which the PAD 13 goes negative with respect to VDDIO. As soon as the voltage at VDDIO becomes equal to the sum of turn on voltage of NMOS MN2 and diode D2 and a voltage drop across R2, a current starts flowing from VDDIO into PAD 13 through diode D2 and NMOS MN2. However, if this voltage at PAD 13 is larger than the breakdown voltage of MP1, then the semiconductor junction between the drain-bulk of MP1 is broken and current I2, as shown in FIG. 2, starts flowing through the drain-bulk of MP1.

However, the breakdown voltage of the drain-bulk junction of a PMOS transistor is greater than that of an NMOS transistor, so ESD events of the fourth type are less of a concern. This is well known in the art, so efforts are typically made to help protect the NMOS transistor, which in the examples presented is transistor MN1.

Some prior attempts have been made to enhance ESD protection of the driver circuit by using non-silicide transistors since silicide transistors have a lower breakdown voltage compared to non-silicide transistors. Other prior attempts to enhance ESD protection of the driver circuit increase the gate length of the transistors, or by utilize silicided transistors with an external series resistance at their sources and drains. However, the area cost of implementing these solutions is high, doubling the area (or more) of the resulting devices. In addition, while these designs do improve ESD robustness, drain-bulk junction breakdown is still probable at a certain drain to source voltages (considering that the bulk and source are shorted).

Therefore, further development in the area of enhancing ESD resistance and protection is still needed.

### SUMMARY

In a first embodiment, there is an output driver and a protection circuit. The output driver includes a first NMOS transistor with its drain coupled to a PAD, its source coupled to a reference voltage, and its gate coupled to a first logic circuit. The output driver also includes a first PMOS transistor with its drain coupled to the PAD, its gate coupled to a second logic circuit, and its source coupled to a supply voltage. The protection circuit includes a diode having its cathode coupled to the PAD and its anode coupled to the reference voltage. The protection circuit also includes a second NMOS transistor having its drain coupled to the PAD through a capacitor, its source coupled to the reference voltage, and its gate coupled to the supply voltage. A resistor is coupled between the bulk of the first NMOS transistor and the drain of the second NMOS transistor. In the presence of an ESD event where the PAD goes positive with respect to the reference voltage, the second NMOS transistor switches off. In an absence of the ESD event, the second NMOS transistor remains on.

In a second embodiment, there is an output driver and a protection circuit. The output driver includes a first NMOS transistor with its drain coupled to a PAD, its source coupled to a reference voltage, and its gate coupled to a first logic circuit. The protection circuit includes a diode having its cathode coupled to the PAD and its anode coupled to the reference voltage. The protection circuit also includes a second NMOS transistor having its drain coupled to the PAD through a capacitor, its source coupled to the reference voltage, and its gate coupled to a supply voltage. The drain of the second NMOS transistor is also coupled to a bulk of the first NMOS transistor. A resistor is coupled between the bulk of the first NMOS transistor and the reference voltage. In the presence of an ESD event where the PAD goes positive with respect to the reference voltage, the second NMOS transistor switches off. In an absence of the ESD event, the second NMOS transistor remains on.

In a third embodiment, there is an output driver and a protection circuit. The output driver includes a first NMOS transistor with its drain coupled to a PAD, its source coupled to a reference voltage, and its gate coupled to a first logic circuit. The protection circuit includes a diode having its cathode coupled to the PAD and its anode coupled to the reference voltage. The protection circuit also includes a second NMOS transistor having its drain coupled to the PAD through a capacitor and a resistor, its source coupled to the reference voltage, and its gate coupled to a supply voltage. The drain of the second NMOS transistor is also coupled to a bulk of the first NMOS transistor. In the presence of an ESD event where the PAD goes positive with respect to the reference voltage, the second NMOS transistor switches off. In an absence of the ESD event, the second NMOS transistor remains on.

In the above three embodiments, the output driver may include a first PMOS transistor having its source coupled to the supply voltage, its drain coupled to the PAD, and its gate coupled to a second logic circuit.

### BRIEF DESCRIPTION OF THE DRAWINGS

FIG. 1 is a block diagram of a prior art electrostatic discharge (ESD) protection circuit when undergoing a ‘positive’ ESD event at a PAD node with respect to the ground VSSIO.

FIG. 2 is a block diagram of the prior art ESD protection circuit when undergoing a ‘negative’ ESD event at a PAD node with respect to the supply voltage VDDIO.

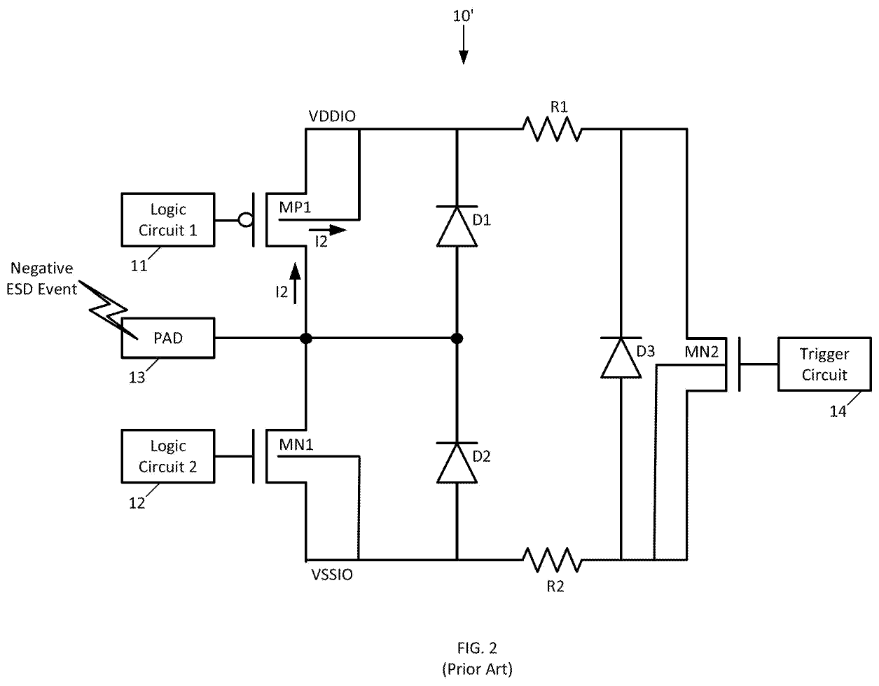

FIG. 3 is a block diagram of a first embodiment of an ESD protection circuit disclosed herein.

FIG. 4 is a block diagram of a second embodiment of an ESD protection circuit disclosed herein.

FIGS. 5A and 5B show a comparison between transistor currents of the driver circuit with ESD protection circuit disclosed herein (FIG. 5A) and transistor currents of the driver circuit with a prior art ESD protection circuit during an ESD event, considering that the voltage drop across the ESD network is equal to or greater than the breakdown voltage of the device (FIG. 5B).

FIGS. 6A and 6B show a comparison between leakage currents of the driver circuit with ESD protection circuit disclosed herein (FIG. 6A) and leakage currents of the driver circuit prior art ESD protection circuit (FIG. 6B) during normal operation of the circuit with a pulse rise and fall time of 100 psec and a frequency of 100 KHz at the driver input node.

FIGS. 7A and 7B show another comparison between leakage currents of the driver circuit with ESD protection circuit disclosed herein (FIG. 7A) and leakage currents of the prior art ESD protection circuit (FIG. 7B) during normal operation of the circuit with pulse rise and fall time of 100 psec and a frequency of 200 MHz at the driver input node.

FIG. 8 is a block diagram of a third embodiment of an ESD protection circuit disclosed herein.

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown, but is to be accorded the widest scope consistent with the principles and features disclosed or suggested herein.

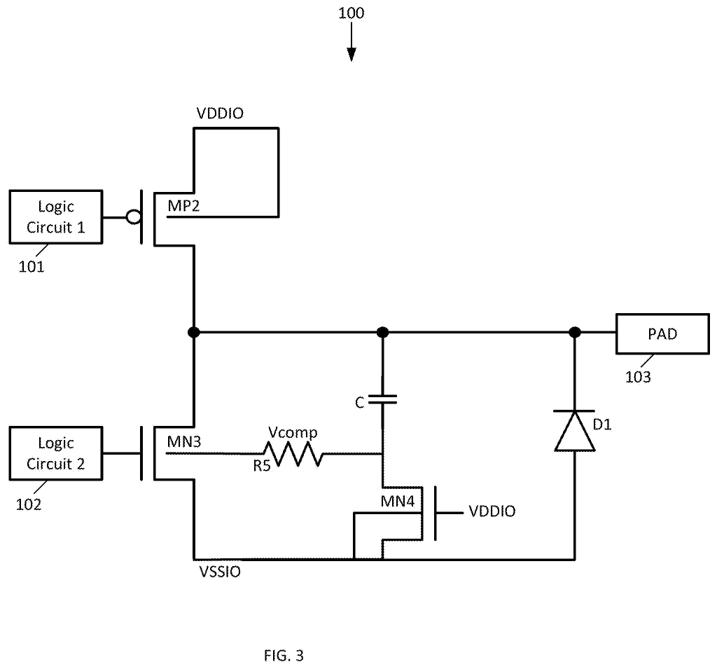

With initial reference to FIG. 3, a first embodiment of an ESD protected circuit 100 is now described. The circuit 100 includes a PMOS transistor MP2 and an NMOS transistor MN3. The PMOS transistor MP2 is connected to conduct between positive input/output (I/O) supply voltage node VDDIO and the PAD 13, and the NMOS transistor MN3 is connected to conduct between the PAD 13 and a ground/negative I/O supply voltage node VSSIO. The gates of the transistors MP2 and MN3 are respectively driven by the outputs of logic circuits 101 and 102. Diode D1 is connected between the PAD 103 and VSSIO with its cathode being connected to the PAD 103 and its anode to VSSIO.

In one binary state of an output signal, the gates of the transistors MP2 and MN3 are driven with voltages that turn off transistor MN3 and turn on transistor MP2 to pull the PAD 103 up to the VDDIO node. In the other binary output state, the gates of the transistors MP2 and MN3 are driven with voltages that turn off transistor MP2 and turn on transistor MN3 to pull the PAD 13 down to the VSSIO node.

NMOS transistor MN4 has its drain coupled to the PAD 103 through capacitor C (realized using a lumped capacitor or using capacitive behavior of any device), its source connected to VSSIO, and its gate connected to VDDIO. Note that VDDIO will be in a binary high state during normal operation of the chip, coupling the bulk of the NMOS MN3 to ground through a small channel resistance of NMOS MN4 and resistor R5. Since the leakage current through the parasitic diode between the drain-bulk of NMOS MN3 is negligible, the voltage drop across the channel resistance of NMOS MN4 and resistor R5 is insignificant, and hence the bulk of NMOS MN3 is at a near to zero potential.

During an ESD event at PAD 103, when PAD 103 is negative with respect to VSSIO, the diode D1 and the parasitic drain-bulk diode in NMOS MN3 become forward biased once the potential difference between ground and PAD 103 becomes equal to their forward turn on voltages, after which the current starts flowing from ground into PAD 103. Approximately or nearly all the current starts flowing through diode D1 due to the low inherent resistance compared to the parasitic drain-bulk diode in NMOS MN3. Since the forward turn on voltage of the diode D1 is small compared to the breakdown voltage of the NMOS MN3, the diode D1 is successful at protecting the NMOS MN3.

However, a particular concern arises when an ESD event occurs at PAD 103 during which the PAD 103 is positive with respect to VSSIO, the drain-bulk junction of NMOS MN3 will break down if the drop across ESD network is equal to or greater than the breakdown voltage of drain-bulk diode of the device NMOS MN3. To avoid this situation, the breakdown voltage, BVth, of the drain-bulk junction is effectively raised.

During an ESD event at PAD 103, in which PAD 103 is positive with respect to VSSIO, VDDIO floats, turning NMOS MN4 off, isolating the bulk of the NMOS MN3 from VSSIO, and coupling the bulk of the NMOS MN3 to PAD 103 through the capacitor C and resistor R5. As the voltage starts rising at the PAD 103, the capacitor C charges and then starts charging the bulk of NMOS MN3 to almost to same voltage through resistor R5. Therefore, the potential difference between the drain-bulk of NMOS MN3 is very small and far lower than the breakdown voltage of the diode between the drain-bulk of NMOS MN3.

Note that since the bulk of NMOS MN3 gets charged by the ESD event to a higher potential through R5 and C, the bulk-source parasitic diode in NMOS MN3 becomes forward biased but the current from PAD 103 to VSSIO through this parasitic bulk-source diode is small due to the high resistance of R5. Thus, with the parasitic drain-bulk diode almost shorted together and the parasitic bulk-source diode being forward biased, the current starts flowing from the drain of NMOS MN3 into the source of the NMOS MN3 through the parasitic NPN bipolar junction transistor formed from the parasitic drain-bulk and bulk-source diodes of MN3. Thus, there is an active current path from PAD 103 to VSSIO in the driver circuit which draws current as per the quiescent point of the parasitic NPN bipolar junction transistor of the NMOS MN3 without damaging the NMOS MN3 as there is no possible regenerative path in the circuit.

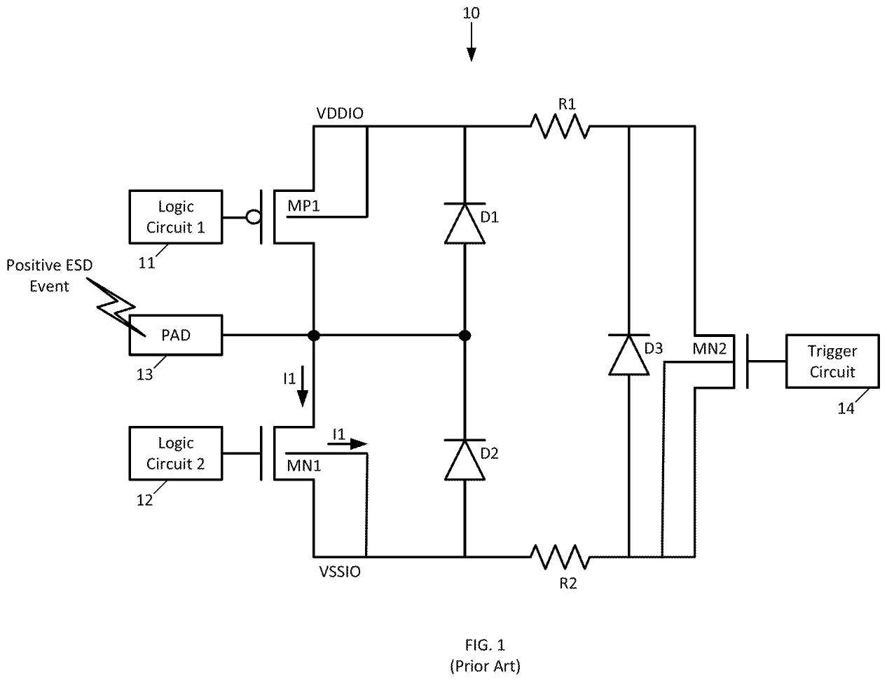

By carefully designing the layout of parasitic bulk-source diode of the NMOS MN3 and capacitance C, current can be passed from PAD 103 into VSSIO depending upon the value of capacitance C, as soon as the parasitic bulk-source diode of the NMOS MN3 turns on by removing the resistor R5 or setting its value to zero. Depending upon the size of parasitic bipolar junction transistor NPN and parasitic bulk-source diode of NMOS MN3, the dependence on RC triggered NMOS NM4 (shown in FIG. 1) to discharge the current from PAD 103 to VSSIO can be avoided.

Thus, by dynamically coupling the bulk of NMOS MN3 to ground in a normal state but to its drain in an ESD event, the probability of the NMOS MN3 device breaking down can be avoided without impacting the normal operation of the circuit.

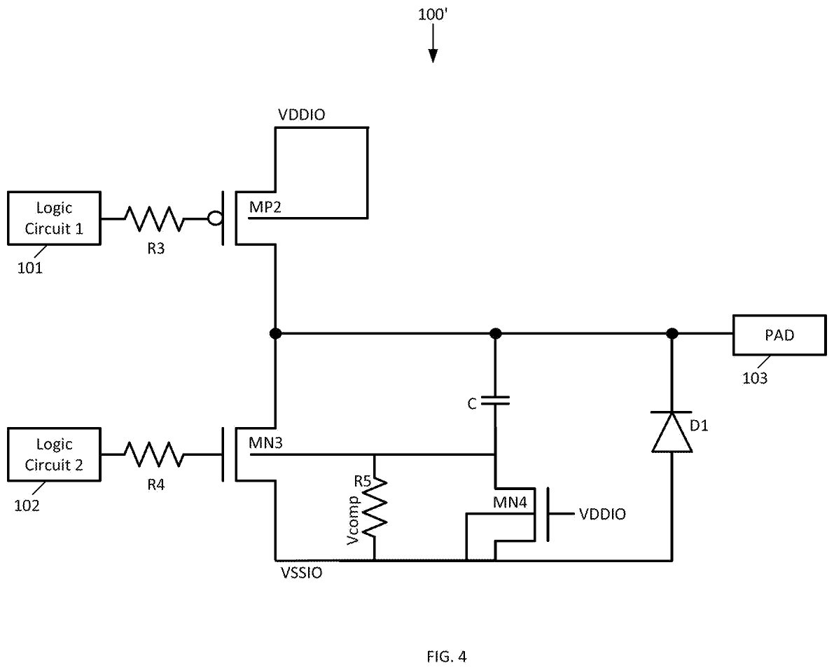

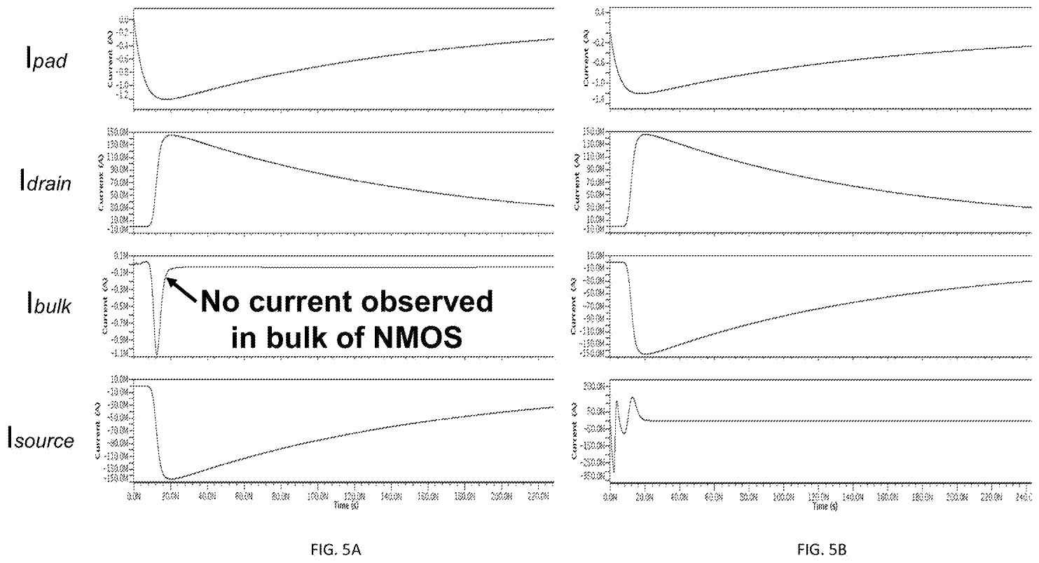

Another embodiment of the ESD protected circuit 100′ is shown in FIG. 4. The intent of this ESD protected circuit 100′ is to bias the bulk of the NMOS MN3 to a voltage drop across resistor R5 when the parasitic bulk-source diode of the NMOS MN3 becomes forward biased, during an ESD event in which the voltage at the PAD 103 is raised above VSSIO. The currents across NMOS MN3 during an ESD event when the voltage across the PAD is raised above the VSSIO are shown in FIG. 5A as compared to those of the equivalent prior art transistor (considering a scenario when voltage drop across the ESD network is equal or larger than the breakdown voltage of the NMOS MN3) as shown in FIG. 5B. As can be seen in the trace of the bulk current Ibulk in FIG. 5A, at the drain current spike resulting from a positive ESD event, almost no current is observed in the bulk of NMOS MN3. Compare this to the much greater bulk current spike shown in FIG. 5B. Thus, the designs of FIGS. 3-4 avoid bulk current injection which occurs in the prior art and which is the signature of breakdown of the NMOS drain-bulk junction NMOS MN3.

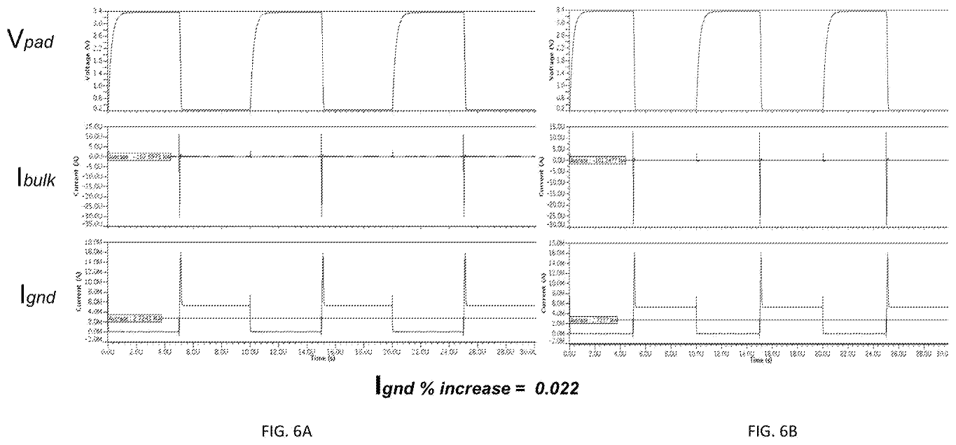

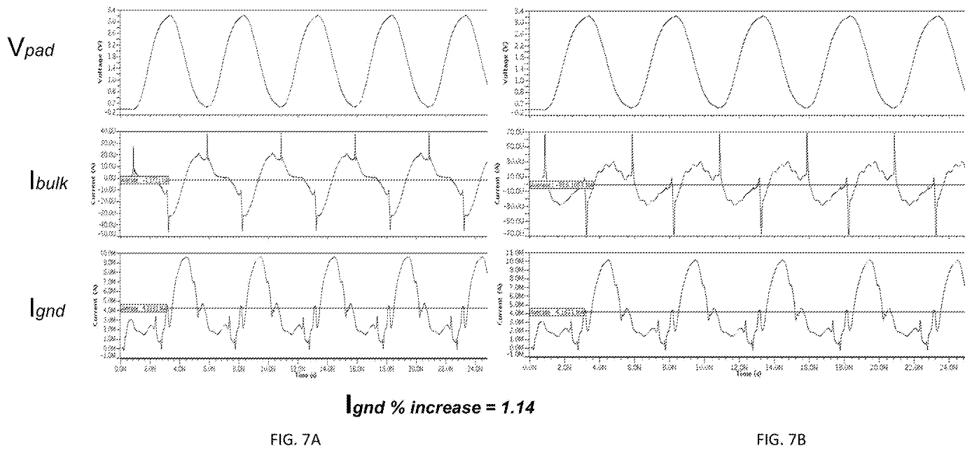

As shown in FIG. 6A and FIG. 7A during the normal operation of the circuit even at quite a high rise pulse at the PAD 103, the capacitor C is not able to draw significant leakage current through the parasitic bulk-source diode of NMOS MN3.

Note that NMOS MN3 does not have its gate grounded, and does not have its gate shorted to its source. Therefore, this design stands apart from prior designs that function by strongly turning on the parasitic transistor of their corresponding driver NMOS transistor.

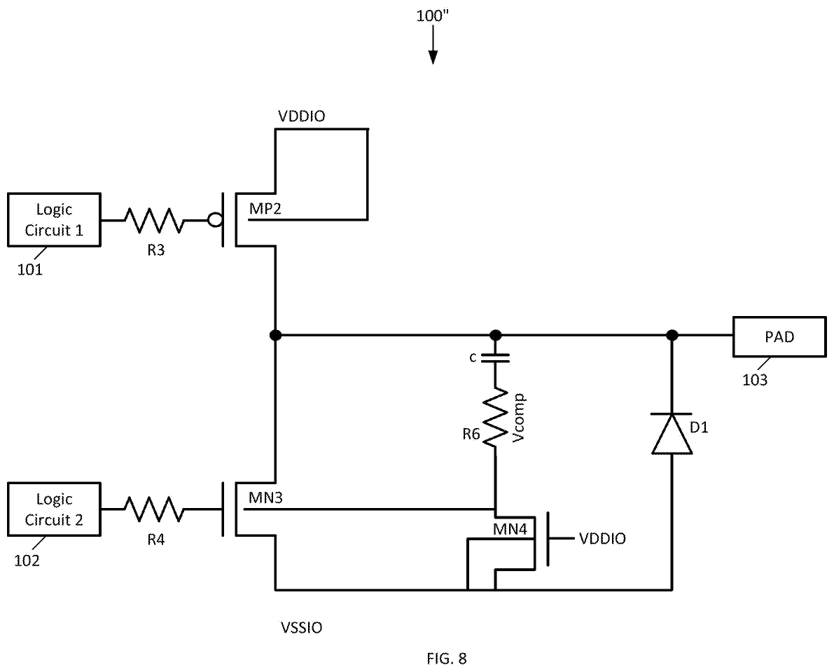

Another embodiment of the ESD protected circuit 100″ is shown in FIG. 8. This ESD protected circuit 100″ differs from that of FIG. 3 in that here, the drain of the NMOS MN4 is connected to the bulk of the NMOS MN3 and is also directly electrically connected to a first terminal of a resistor R6. A second terminal of the resistor R6 is connected to a first terminal of a capacitor C. A second terminal of the capacitor C is connected to the PAD 103. Operation of this ESD protected circuit 100″ is the same as that of FIG. 3.

While this disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A circuit, comprising:
a logic circuit;
an output driver for the logic circuit, the output driver comprising:
a first NMOS transistor having a gate coupled to the logic circuit, a source coupled to a reference voltage, and a drain coupled to a PAD;
a protection circuit for the output driver, the protection circuit comprising:
a second NMOS transistor having a drain coupled to the PAD, a source coupled to the reference voltage, and a gate coupled to a supply voltage; and
a resistor coupled between the drain of the second NMOS transistor and a bulk of the first NMOS transistor;
wherein the supply voltage is floating initially when an electrostatic discharge (ESD) event raises potential at the PAD to be positive with respect to the reference voltage, such that the second NMOS transistor turns off, resulting the bulk of the first NMOS transistor being isolated from the reference voltage; and
wherein the supply voltage remains sufficiently high in absence of an ESD event so that the second NMOS transistor turns on to couple the bulk of the first NMOS transistor to the source of the first NMOS transistor.

2. The circuit of claim 1, wherein the gate of the first NMOS transistor is directly electrically connected to an output of the logic circuit, wherein the source of the first NMOS transistor is directly electrically connected to the reference voltage, and wherein the drain of the first NMOS transistor is directly electrically connected to the PAD.

3. The circuit of claim 1, wherein the resistor has a first terminal coupled to the source of the second NMOS transistor and a second terminal coupled to the bulk of the first NMOS transistor and the drain of the second NMOS transistor.

4. The circuit of claim 1, wherein the resistor has a first terminal directly electrically connected to the source of the second NMOS transistor and a second terminal directly electrically connected to the bulk of the first NMOS transistor and the drain of the second NMOS transistor.

5. The circuit of claim 1, wherein the resistor has a first terminal coupled to the drain of the second NMOS transistor and a second terminal coupled to the bulk of the first NMOS transistor.

6. The circuit of claim 1, wherein the resistor has a first terminal directly electrically connected to the drain of the second NMOS transistor and a second terminal directly electrically connected to the bulk of the first NMOS transistor.

7. The circuit of claim 1, further comprising a capacitor coupled between the PAD and the drain of the second NMOS transistor.

8. The circuit of claim 7, wherein the capacitor is realized using a lumped capacitor.

9. The circuit of claim 7, wherein the capacitor is realized using capacitive behavior of any device.

10. The circuit of claim 1, wherein the first NMOS transistor is silicide or non-silicide.

11. The circuit of claim 1, wherein the drain of the second NMOS transistor is coupled to the bulk of the first NMOS transistor; and wherein the drain of the second NMOS transistor is coupled to the PAD through the resistor and a capacitor.

12. The circuit of claim 1, wherein the drain of the second NMOS transistor is direct electrically connected to the bulk of the first NMOS transistor; and wherein the drain of the second NMOS transistor is coupled to the PAD by being directly electrically connected to a first terminal of the resistor, a second terminal of the resistor being directly electrically connected to a first terminal of a capacitor, and a second terminal of the capacitor being directly electrically connected to the PAD.

13. The circuit of claim 1, wherein the output driver further comprises a first PMOS transistor having a source coupled to the supply voltage, a drain coupled to the PAD, and a gate coupled to the logic circuit.

14. A circuit, comprising:
a logic circuit;
a first NMOS transistor having a gate coupled to the logic circuit, a drain coupled to a PAD, and a source coupled to a reference voltage; and
a protection circuit coupled to the PAD and to a bulk of the first NMOS transistor, the protection circuit configured to:
couple the PAD to the bulk of the first NMOS transistor when an electrostatic discharge (ESD) event occurs; and
couple the bulk of the first NMOS transistor to the source of the first NMOS transistor in absence of the ESD event.

15. The circuit of claim 14, wherein the protection circuit comprises a switch coupled between the bulk and source of the first NMOS transistor; wherein the switch remains closed in the absence of the ESD event to thereby short the bulk of the first NMOS transistor to the source of the first NMOS transistor; and wherein the switch opens when the ESD event occurs to thereby permit use of the ESD event to bias the bulk of the first NMOS transistor.

16. The circuit of claim 14, wherein the protection circuit comprises a resistor coupled between the PAD and the bulk of the first NMOS transistor, the resistor being coupled to the PAD through a capacitor.

17. The circuit of claim 14, wherein the protection circuit comprises a resistor coupled between the bulk of the first NMOS transistor and the reference voltage.

18. The circuit of claim 14, wherein the first NMOS transistor can be silicide or non-silicide.

19. The circuit of claim 14, wherein the capacitor is realized using a lumped capacitor.

20. The circuit of claim 14, wherein the capacitor is realized using capacitive behavior of any device.

21. The circuit of claim 14, further comprising a first PMOS transistor having a gate coupled to the logic circuit, a source coupled to a supply voltage, and a drain coupled to the PAD.

22. A method of protecting a first NMOS transistor, comprising:
in a presence of an electrostatic discharge (ESD) event at a PAD coupled to a drain of the first NMOS transistor, using a potential at the PAD resulting from the ESD event to bias a bulk of the first NMOS transistor; and
in an absence of the ESD event at the PAD, coupling the bulk of the first NMOS transistor to a source of the first NMOS transistor.

23. The method of claim 22, wherein the potential at the PAD is used to bias the bulk of the first NMOS transistor using a resistor and a capacitor.

24. The method of claim 22, wherein the potential at the PAD is used to bias the bulk of the first NMOS transistor by using the potential at the PAD to charge a capacitor and applying the charge from the capacitor to the bulk of the first NMOS transistor through a resistor.

25. A circuit, comprising:
a logic circuit;
an output driver for the logic circuit, the output driver comprising:
a first transistor having a control terminal coupled to the logic circuit, a second conduction terminal coupled to a reference voltage, and a first conduction terminal coupled to a PAD;
a protection circuit for the output driver, the protection circuit comprising:
a second transistor having a first conduction terminal coupled to the PAD, a second conduction terminal coupled to the reference voltage, and a control terminal coupled to receive a supply voltage; and
a resistor coupled to the first conduction terminal of the second transistor and a bulk of the first transistor.

26. The circuit of claim 25, wherein the resistor has a first terminal coupled to the first conduction terminal of the second transistor and a second terminal coupled to the bulk of the first transistor.

27. The circuit of claim 25, wherein the resistor has a first terminal coupled to the first conduction terminal of the second transistor and to the bulk of the first transistor, and a second terminal coupled to the reference voltage.

28. The circuit of claim 25, wherein the resistor has a first terminal coupled to the first conduction terminal of the second transistor and a second terminal coupled to a first conduction terminal of a capacitor, a second conduction terminal of the capacitor being coupled to the PAD.

29. The circuit of claim 25, wherein the first transistor is a first NMOS transistor, where the first conduction terminal of the first NMOS transistor is a drain, where the second conduction terminal of the first NMOS transistor is a source, and where the control terminal of the first NMOS transistor is a gate.

30. The circuit of claim 25, wherein the second transistor is a second NMOS transistor, where the first conduction terminal of the second NMOS transistor is a drain, where the second conduction terminal of the second NMOS transistor is a source, and wherein the control terminal of the second NMOS transistor is a gate.

31. The circuit of claim 25, wherein the first conduction terminal of the second transistor is coupled to the PAD through a capacitor.

32. The circuit of claim 25, wherein the output driver further comprises a second transistor having a control terminal coupled to the logic circuit, a second conduction terminal coupled to the PAD, and a first conduction terminal coupled to the supply voltage.

33. A circuit, comprising:
a first NMOS transistor having a drain coupled to a PAD, a source coupled to a reference voltage, and a gate;
a second NMOS transistor having a drain coupled to the PAD through a capacitor, a source coupled to the reference voltage, and a gate coupled to a supply voltage; and
a resistor coupled between the drain of the second NMOS transistor and a bulk of the first NMOS transistor.

34. The circuit of claim 33, further comprising a diode having a cathode coupled to the PAD and an anode coupled to the reference voltage.

35. The circuit of claim 33, wherein the gate of the first NMOS transistor is coupled to a second logic circuit; and further comprising a first PMOS transistor having a source coupled to the supply voltage, a drain coupled to the PAD, and a gate coupled to a first logic circuit.

36. A circuit, comprising:
a first NMOS transistor having a drain coupled to a PAD, a source coupled to a reference voltage, and a gate;
a second NMOS transistor having a drain coupled to a bulk of the first NMOS transistor, the drain of the second NMOS transistor also coupled to the PAD through a capacitor, the second NMOS transistor also having a source coupled to the reference voltage and a gate coupled to a supply voltage; and
a resistor coupled between the bulk of the first NMOS transistor and the reference voltage.

37. The circuit of claim 36, further comprising a diode having a cathode coupled to the PAD and an anode coupled to the reference voltage.

38. The circuit of claim 36, wherein the gate of the first NMOS transistor is coupled to a second logic circuit; and further comprising a first PMOS transistor having a source coupled to the supply voltage, a drain coupled to the PAD, and a gate coupled to a first logic circuit.

39. A circuit, comprising:
a logic circuit;
an output driver for the logic circuit, the output driver comprising:
a first NMOS transistor having a gate coupled to the logic circuit, a source coupled to a reference voltage, and a drain coupled to a PAD;
a protection circuit for the output driver, the protection circuit comprising:
a second NMOS transistor having a drain coupled to the PAD, a source coupled to the reference voltage, and a gate coupled to a supply voltage; and
a resistor coupled to the drain of the second NMOS transistor and to a bulk of the first NMOS transistor;
wherein the supply voltage is floating initially when an electrostatic discharge (ESD) event raises potential at the PAD to be positive with respect to the reference voltage; and
wherein the supply voltage remains at a logic high in absence of an ESD event.

40. The circuit of claim 39, wherein the gate of the first NMOS transistor is directly electrically connected to an output of the logic circuit, wherein the source of the first NMOS transistor is directly electrically connected to the reference voltage, and wherein the drain of the first NMOS transistor is directly electrically connected to the PAD.

41. The circuit of claim 39, wherein the resistor has a first terminal directly electrically connected to the source of the second NMOS transistor and a second terminal directly electrically connected to the bulk of the first NMOS transistor and the drain of the second NMOS transistor.

42. The circuit of claim 39, wherein the resistor has a first terminal directly electrically connected to the drain of the second NMOS transistor and a second terminal directly electrically connected to the bulk of the first NMOS transistor.

43. The circuit of claim 39, wherein the drain of the second NMOS transistor is direct electrically connected to the bulk of the first NMOS transistor; and wherein the drain of the second NMOS transistor is coupled to the PAD by being directly electrically connected to a first terminal of the resistor, a second terminal of the resistor being directly electrically connected to a first terminal of a capacitor, and a second terminal of the capacitor being directly electrically connected to the PAD.

44. The circuit of claim 39, wherein the output driver further comprises a first PMOS transistor having a gate coupled to the logic circuit, a source coupled to the supply voltage, and a drain coupled to the PAD.
